(19) United States
(12) Patent Application Publication
(10) Pub. No.: US 2022/0181247 A1
(43) Pub. Date: Jun. 9, 2022

(54) Chip Module, Use of Chip Module, Test Arrangement and Test Method

(71) Applicant: First Sensor AG, Berlin (DE)

(72) Inventors: Stephan Dobritz, Dresden (DE); Christoph Findeisen, Dresden (DE); Michael Pierschel, Berlin (DE)

(73) Assignee: First Sensor AG, Berlin (DE)

(21) Appl. No.: 17/518,987

(22) Filed: Nov. 4, 2021

(30) Foreign Application Priority Data
Dec. 4, 2020 (DE) 102020215388.4

(51) Int. Cl. H01L 23/498; H01L 23/00; G01R 19/165; G01R 27/14; G01S 7/481; G01S 17/08; G01R 31/66

(52) U.S. Cl. CPC H01L 23/49838; H01L 23/3185; H01L 23/49816; H01L 23/49827; H01L 24/33; G01R 19/16571; G01R 27/14; G01S 7/4813; G01S 17/08; G01R 31/66; H01L 2224/32227; H01L 2224/33515; H01L 2224/32111; H01L 24/48; H01L 2224/48227; H01L 24/73; H01L 2224/73265; H01L 24/83; H01L 2224/83192; H01L 2224/83951; H01L 24/32

(57) ABSTRACT

A chip module includes a chip having a front side and a rear side, a chip carrier having an upper side facing the chip, a contact layer formed of an electrically conductive material and arranged on the upper side of the chip carrier between the rear side of the chip and the upper side of the chip carrier, and an electrically conductive adhesive arranged on an upper side of the contact layer facing the chip. The electrically conductive adhesive connects the upper side of the contact layer and the rear side of the chip. The contact layer has a plurality of regions electrically insulated from each other and each electrically connected to the chip by the electrically conductive adhesive.

### CROSS-REFERENCE TO RELATED APPLICATIONS

This application claims the benefit of the filing date under 35 U.S.C. § 119(a)-(d) of German Patent Application No. 102020215388.4, filed on Dec. 4, 2020.

### FIELD OF THE INVENTION

The present application relates to a chip module, to the use of such a chip module, to a test arrangement for testing a contacting of the chip module, and to a test method for testing the contacting of the chip module.

### BACKGROUND

Semiconductor components usually use a front side of a wafer or chip for the arrangement of electrically active elements. These semiconductor components are mounted on a chip carrier and electrically contact the chip carrier. Many of these semiconductor components require an electrically conductive contact to be made on the rear side of the chip. To ensure a sufficiently good electrical contact, wafer backs are usually metallized, very often by a metal sandwich layer with a final gold surface.

The connection between the chip and the chip carrier has to fulfill two essential functions. In this case, on the one hand, a sufficient mechanical connection must be established that guarantees the strength, in particular the adhesive strength, under the conditions of use of the component. Furthermore, this connection should ensure a stable electrical connection under conditions of use. The combination of these two functions creates high demands on the adhesive connection or soldered or sintered connection.

### SUMMARY

A chip module includes a chip having a front side and a rear side, a chip carrier having an upper side facing the chip, a contact layer formed of an electrically conductive material and arranged on the upper side of the chip carrier between the rear side of the chip and the upper side of the chip carrier, and an electrically conductive adhesive arranged on an upper side of the contact layer facing the chip. The electrically conductive adhesive connects the upper side of the contact layer and the rear side of the chip. The contact layer has a plurality of regions electrically insulated from each other and each electrically connected to the chip by the electrically conductive adhesive.

### BRIEF DESCRIPTION OF THE DRAWINGS

The invention will now be described by way of example with reference to the accompanying Figures, of which:

FIG. 1 is a schematic plan view of a chip module according to an embodiment;

FIG. 2 is a sectional side view of the chip module of FIG. 1 without a chip;

FIG. 3 is a sectional side view of the chip module of FIG. 2 with an electrically conductive adhesive;

FIG. 4 is a sectional side view of the chip module of FIG. 3 with the chip;

FIG. 5 is a sectional side view of the chip module of FIG. 4 with a housing;

FIG. 6 is a sectional side view of the chip module of FIG. 5 with solder balls;

FIG. 7 is a schematic plan view of a chip module according to another embodiment;

FIG. 8 is a sectional side view of the chip module of FIG. 7 without a chip;

FIG. 9 is a sectional side view of the chip module of FIG. 8 with an electrically conductive adhesive;

FIG. 10 is a sectional side view of the chip module of FIG. 9 with the chip;

FIG. 11 is a sectional side view of the chip module of FIG. 11 with a housing;

FIG. 12 is a sectional side view of the chip module of FIG. 12 with solder balls;

FIG. 13 is a schematic plan view of a chip module according to another embodiment;

FIG. 14 is a sectional side view of the chip module of FIG. 13 without a chip;

FIG. 15 is a sectional side view of the chip module of FIG. 14 with an electrically non-conductive adhesive;

FIG. 16 is a sectional side view of the chip module of FIG. 15 with the chip;

FIG. 17 is a sectional side view of the chip module of FIG. 16 with an electrically conductive adhesive;

FIG. 18 is a sectional side view of the chip module of FIG. 17 with a housing;

FIG. 19 is a schematic sectional side view of a test arrangement with a chip module according to an embodiment;

FIG. 20 is a schematic sectional side view of a test arrangement with a chip module according to another embodiment;

FIG. 21 is a schematic sectional side view of a test arrangement with a chip module according to another embodiment; and

FIG. 22 is a schematic sectional side view of a test arrangement with a chip module according to another embodiment.

### DETAILED DESCRIPTION OF THE EMBODIMENTS

The present invention shall be explained in more detail hereafter with reference to the figures. Same parts are provided with the same reference numerals and the same component names. Furthermore, some features or combinations of features from the different embodiments shown and described can in themselves represent solutions that are independent according to the invention. Recurring features are provided with the same reference symbols.

FIG. 1 shows a schematic illustration of a chip module in a plan view. The chip module comprises a chip 1, outlined in FIG. 1 with a dashed line and shown transparently in order to reveal the underlying structure. Furthermore, the chip module comprises a chip carrier 2, on the upper side 21 of which a contact layer 3 is arranged. The contact layer 3 is electrically conductive.

The contact layer 3 comprises at least three, and in the shown embodiment four regions 3A, 3B, 3C, 3D, that are electrically insulated from each other in the shown embodiment. In the present example, the regions 3A to 3D that are insulated from each other are rectangular. In other examples, these regions 3A to 3D can also have other shapes, for example square, circular, elliptical or combinations of such shapes. The regions 3A to 3D each protrude beyond the chip 1. In other embodiments, the contact layers 3 can have more than four mutually insulated regions. The regions insulated from each other can also be referred to as contact regions.

In one embodiment, the chip 1 can have a length of at least 1 mm, at least 1.5 mm, or at least 2 mm. Additionally or alternatively, the chip 1 can have a length of at most 200 mm, at most 100 mm, or at most 50 mm. However, chips 1 with even greater dimensions can also be processed. In one embodiment, the chip 1 can have a width of at least 1 mm, at least 1.5 mm, or at least 2 mm. Additionally or alternatively, the chip 1 can have a width of at most 200 mm, at most 100 mm, or at most 50 mm.

The chip 1, in the embodiment shown in FIG. 1, has a width B1 of 8 mm and a length L1 of 15 mm. The contact layer 3 has a length L3 of 17 mm and a width B3 of 10 mm. The individual regions 3A-3D insulated from each other have identical dimensions. Each of the regions 3A to 3D has a length L3A of 7.5 mm and a width B3A of 4 mm.

In the present case, the chip 1 can be understood to mean a microelectronic component, in particular a semiconductor chip or a microsystem. The chip 1 has a front side 11 and a rear side 12. The front side 11 usually carries the active semiconductor structures. The chip 1 can have electrical contacts on its rear side, for example for supplying an electrical component or microsystem integrated in the chip with a voltage, and/or for communicating with the electrical component and/or microsystem. Additionally or alternatively, the chip 1 can have further electrical contacts on its front side.

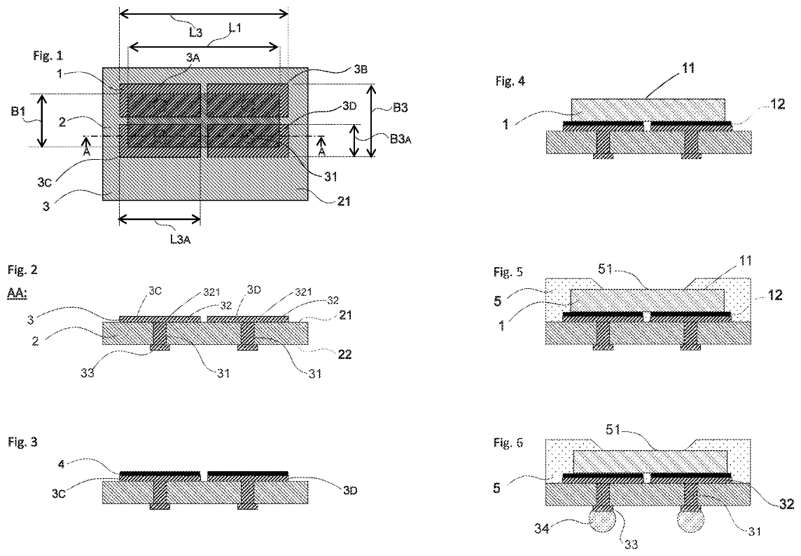

In the present example, the chip carrier 2 comprises FR4 or its derivatives. FR4 is a printed circuit board base material, such as a glass-reinforced epoxy laminate material. An embodiment consisting of ceramic or comprising ceramic is also possible. Through-holes which allow a through-hole plating 31 are provided in the chip carrier 2. In each of the mutually insulated regions 3A to 3D, the contact layer 3 has a plated-through hole 31 which connects a contact surface 32, which is arranged on the upper side 21 of the chip carrier 2, to an underside 22 of the chip carrier 2. This can have the advantage that each of the regions 3A to 3D insulated from each other can be controlled electrically independently of the others via the plated-through hole 31. On the underside of the chip carrier 2, the contact layer 3 has a soldering surface 33 at the lower end of the plated-through hole 31, as shown in FIG. 2.

In one embodiment, the chip 1 and the contact layer 3 are arranged centered in such a way that a surface center point of the upper side of the contact layer 3 is at a minimum distance from a surface center point of the rear side 12 of the chip 1. The contact layer 3 comprises the regions 3A-3D that are electrically insulated from each other, such that the surface of the contact layer 3 is defined by outer edges of the regions that are electrically insulated from each other. The center point of a surface of the contact layer 3 defined in this way can thus lie in one of the regions 3A-3D insulated from each other, or also in a region that lies between the regions 3A-3D insulated from each other.

An electrically conductive adhesive 4 is arranged on an upper side of the contact layer 3—more precisely, on each of the upper sides 321 of the respective contact surfaces 32. This is shown in FIG. 3, which substantially corresponds to FIG. 2, but additionally shows the arrangement of the adhesive 4. In FIG. 3, it can be seen that the adhesive 4 is arranged on an upper side 321 of the contact surfaces 32 in such a way that the regions insulated from each other do not come into contact with the adhesive. In an embodiment, a conductive silver adhesive is selected as the electrically conductive adhesive 4. In the present case, the electrically conductive adhesive 4 can comprise a soldered connection or a sintered layer or can be designed as a soldered connection or sintered connection.

The contact layer 4 can, for example, comprise gold and/or other noble metals and/or other metals. The electrically conductive adhesive 4 can comprise, for example, one polymer or several polymers, for example epoxy resin, acrylate, silicone, polyurethane and/or esters. The electrically conductive adhesive 4 can comprise silver particles and/or one or more other conductive substances, for example graphite. The conductive substances can in particular be embedded in the polymer(s).

FIG. 4 shows the sectional view of the chip module of FIGS. 2 and 3, the chip 1 also being shown. The rear side 12 of the chip 1 rests on the electrically conductive adhesive layer 4. In this way, the regions insulated from each other can contact different regions of the rear side 12 of the chip. Contacts of the chip 1 which are arranged on the rear side 21 can thus be electrically connected to the contact surfaces 32, the plated-through holes 31, and the soldering surfaces 33 via the electrically conductive adhesive 4.

FIG. 5 shows the sectional view of FIG. 4, a housing 5 also being shown in the form of a potted housing. In the example shown, the housing 5 comprises an epoxy-based potting. In other examples, the housing 5 can comprise other materials, for example injection molding materials, paints and coatings, and mold compounds. A mold compound may be a composite of plastic injection molding compounds. The housing 5 at least partially, and in an embodiment completely, encloses the chip 1 and the contact layer 3, in particular the regions of the contact layer 3 that are electrically insulated from each other. The housing 5 can in particular be arranged on the upper side of the chip carrier. The housing 5 can comprise a cover and/or a frame and/or a window and/or window panes. The housing 5 can protect the chip 1 and the contact layer 3 from contamination and/or impacts.

The housing 5 as shown in FIG. 5 has an optical window 51. The optical window 51 is arranged on a front side 11 of the chip 1, such that it can be used, for example, in a LIDAR sensor. A LIDAR sensor is used for light detection and ranging, where a distance determination is performed by light. The housing 5 can include, for example, one or more window panes. Furthermore, the housing 5 can comprise a light source, for example a radiator, a laser chip and/or a further chip, for example a temperature sensor. A light source, for example in the form of a radiator, a laser chip and/or a further chip, for example a temperature sensor, can additionally or alternatively be mounted on the housing 5.

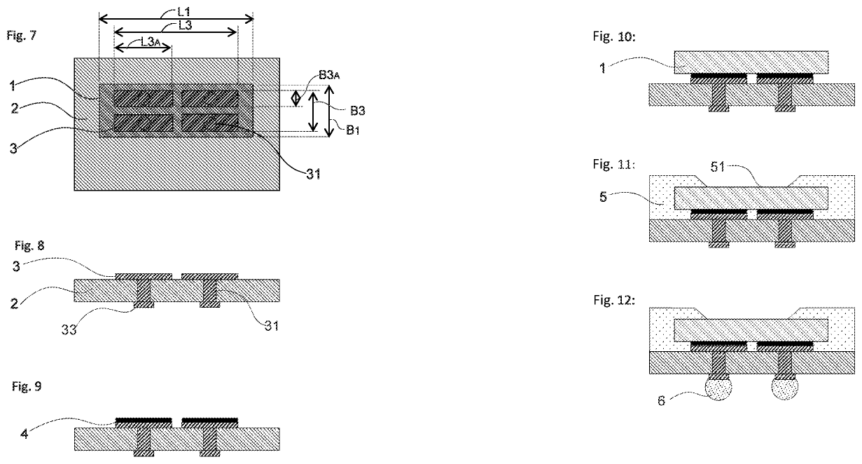

In FIG. 6, solder balls 34 are additionally arranged on the soldering surfaces 33. In another embodiment, the solder balls 34 can be arranged as an alternative to the soldering surfaces 33. This can have the advantage that the chip module can be arranged on a circuit board with correspondingly arranged contacts, and connected to these contacts in a simple manner, for example by fusing the soldering surfaces 33 and/or solder balls 34 with the contacts, for example to form a so-called ball grid array. At greater chip or housing edge lengths, differing thermal expansion can have a greater impact. Solder balls or solder ball arrays (BGA) arranged in a matrix can be used to reduce the thermomechanical stress.

The chip module can comprise one or more further chips 1. The features of the present application which are described with regard to one of the chips 2 can be applied analogously to the at least one further chip, or the plurality of further chips. In one embodiment in which the chip module comprises a plurality of chips 1, the chips 1 can have different characteristics. For example, one or more sensor chips, ASICs for signal evaluation, one or more temperature sensors, and/or one or more LEDs can be provided as a light source. Chips of the same type can also be built into a chip module.

In one embodiment, the chip module can comprise passivations. The chip module can be protected from environmental influences by passivation. Passivations can be, for example, lacquers, conformal coatings, potting, glob tops, underfills or mold compounds that are applied over the entire surface or a portion thereof. A conformal coating adapts to the underlying surface structure, a glob top covers or completely encases bond connections or chips, and can be formed of a plastic material. An underfill is a polymer that flows between the chip 1 and the chip carrier and bonds them together; the underfill can serve as additional mechanical fixation and/or to fill cavities.

FIG. 7 shows a chip module that substantially corresponds to that of FIGS. 1 to 5, the lateral dimensions of the chip 1 being greater than the lateral dimensions of the contact layer 3. The chip 1 thus projects beyond the outer edges of the contact surface 3. FIGS. 7-10 show sectional views of FIG. 6. The structure of the chip module corresponds to the structure of the chip module in FIGS. 1-5, such that the embodiment in FIGS. 7-12 substantially corresponds to the example embodiment in FIGS. 2-5, wherein the lateral dimensions of the chip 1 and the contact surfaces 32 differ from those in the example in FIGS. 1-5. The lateral dimensions of the chip 1 and the contact regions 32 are designed in such a way that the chip 1 projects beyond the edges of the contact regions 3 and covers them.

The chip 1 shown in FIGS. 7-12 has a width B1 of 20 mm and a length L1 of 40 mm. The contact layer 3 has a length L3 of 20 mm and a width B3 of 10 mm. The individual regions 3A-3D insulated from each other have identical dimensions. Each of the regions 3A to 3D has a length L3A of 8 mm and a width B3A of 4 mm. With regard to the further features of FIGS. 8 to 12, reference is therefore made to the description of the drawings for FIGS. 2-6, where like reference number refer to like elements.

In the case of very small chips 1 (especially chips with an edge length of less than 2 mm), it may be technologically more favorable to make the contact layer 3 larger than the chip 2. In the case of very large chips, on the other hand, it can be advantageous to select the contact layer edge length to be less than the chip edge length, so that the different expansion behavior has less of an effect.

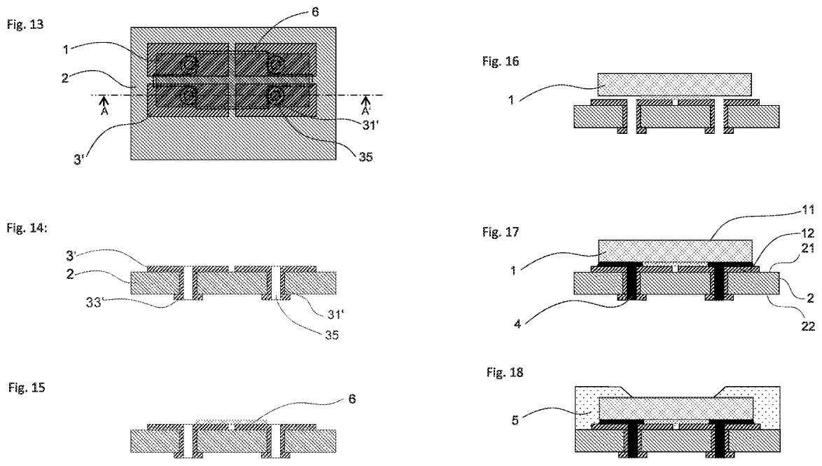

FIGS. 13 to 18 show a further embodiment in a schematic illustration. In FIG. 13, the chip module is shown in a plan view. FIGS. 14 to 18 show the chip module in a sectional view along the section line A-A, wherein only the chip carrier 2 and the contact layer 3′ with plated-through holes 31′ and soldering surfaces 33′ are shown in FIG. 14. The chip module of FIGS. 13 to 18 substantially corresponds to the chip module of FIGS. 1 to 5, with recurring features being provided with the same reference symbols.

The contact layer 3′ of FIGS. 13 to 18, with the mutually insulated regions 3A to 3D, the plated-through holes 31′, and the soldering surfaces 33′, differ from the contact layer 3 of the previous embodiments by the presence of passages 35, in particular in the form of through-holes that extend from an upper side of the contact layer 3′ to the underside of the soldering surface 33′.

FIG. 15 corresponds to FIG. 14, an electrically non-conductive adhesive 6 also being shown. The electrically non-conductive adhesive 6 is arranged in sub-regions on an upper side of the mutually insulated regions 3A to 3D. The non-conductive adhesive 6 forms an essentially rectangular layer which is centered with respect to the chip 1 and the contact layer 3′. The electrically non-conductive adhesive 6 is arranged between the chip 1 and the contact layer 3. The contour of the adhesive print image of the electrically non-conductive adhesive 6 is designed in such a way that the concentric passages 35 are not covered and are not electrically connected to each other. The electrically non-conductive adhesive 6 can consist, for example, of unfilled or filled polymers, the fillers not being electrically conductive. These fillers can be inorganic, such as silicon oxide or aluminum oxide, or, in turn, polymers. The electrically non-conductive adhesive 6 can in particular be bubble-free, i.e., without air inclusions.

The chip 1 is also shown in FIG. 16. In FIG. 17, the electrically conductive adhesive 4 is arranged in regions on the contact layer 3′ and in the passages 35. An underside of the chip module, in particular an underside 22 of the chip carrier 2, is thus electrically connected to a chip rear side 12 via soldering surfaces 33′ and via the electrical adhesive 4. FIG. 18 shows the sectional view of FIG. 17, the chip module also having a housing 5. The housing 5 corresponds to the housing 5 of the previous embodiments.

A sensor can comprise the chip module according to the embodiments described above. The chip module according to the aforementioned embodiments can in particular be used in an optical sensor, in particular a LIDAR sensor. These can be used, for example, in vehicle information or safety systems, for example distance warning systems, and in the field of autonomous driving.

FIG. 19 shows a test arrangement having contact regions 3 which are arranged on an upper side of a chip carrier 2. The test arrangement is used for monitoring the chip 1 contact and/or for localizing defects in the chip 1 contact. The test arrangement is shown schematically in a sectional view. An electrically conductive adhesive 4 is arranged on an upper side of the contact surfaces 3. The chip 1 is arranged on the upper side of the electrically conductive adhesive layer 4, and has smaller lateral dimensions than the contact surfaces 3, which protrude beyond the chip 1. The contact layer 3 is divided into four regions 3A, 3B, 3C, 3D that are electrically insulated from each other. Electrical connection elements 7—in the example shown, a first contacting needle 71 and a second contacting needle 72—are each in contact with regions 3A and 3B, respectively. The contacting needles 71 and 72 are connected to an ammeter A or current measuring device for measuring a test current 8 between the first and the second contacting needles 71, 72. The flow of the test current 8 is shown.

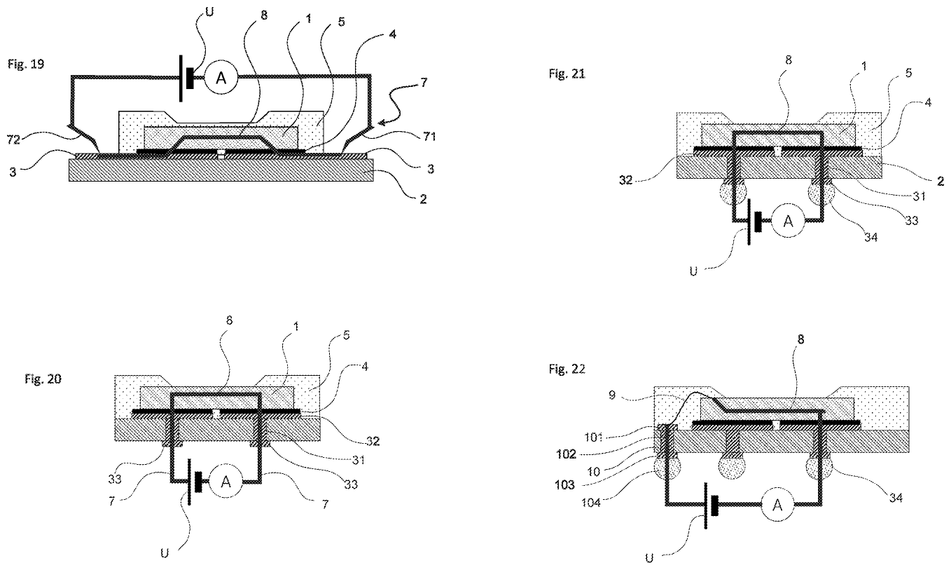

FIG. 20 shows a further possibility for measuring a test current between the electrical connection elements 7. The test arrangement of FIG. 20 comprises a chip module according to FIG. 5. The electrical connection elements 7 are each electrically connected to a soldering surface 33, such that a test current 8 can be sent and measured by the ammeter A.

FIG. 21 shows a test arrangement according to the previous figures, the test arrangement comprising a chip module according to FIG. 6. The electrical connection elements 7 are electrically connected to the solder balls 3.

FIG. 22 shows a test arrangement which substantially corresponds to that of the previous figures. The chip carrier 2 also has an electrical contact element 10, which comprises an upper contact surface 101, a plated-through hole 102, and a lower soldering surface 103. The upper contact surface 101 is arranged on the upper side 21 of the chip carrier 2. The lower soldering surface 22 is arranged on the underside 22 of the chip carrier 2. The plated-through hole 102 is arranged in a passage 35, in particular a through-hole, in the chip carrier 2, and electrically connects the contact surface 101 to the soldering surface 103. On an upper side of the chip 1, a front side contact of the chip 1 is electrically connected to the upper contact surface 101 via a bonding wire 9. The electrical connection elements 7 are electrically connected to a soldering surface 33 or to the soldering surface 103 via solder balls 34 and 104, respectively, such that a test current 8 can be sent and measured by the ammeter A. In this case, the current flow to the chip rear side 12 is measured via the chip 1 via a front side contact, by the bonding wire 9.

It should be noted that the test arrangements of FIGS. 20 to 22 show chip modules whose plated-through holes 31 are not provided with passages 35 corresponding to the passages 35 shown in FIGS. 13 to 18. Of course, the test arrangements described can alternatively include chip modules according to FIGS. 13-18. The illustration of the chip modules in FIGS. 19 to 22 is not to be interpreted as restrictive, but rather as an example.

Each of the test arrangements of FIGS. 19-22 includes a voltage source U. Of course, any test arrangement of the previous figures can also include this voltage source U. The test arrangements shown are suitable for carrying out a test method for monitoring chip contacting and/or for localizing defects, in particular defective regions, of chip contacting.

First, a test current 8 is measured between the first and the second connection element 7, for example the first and the second contacting needle 71, 72. The measured test current 8 can then be compared with a predefined threshold value. If the measured value is greater than the threshold value, this indicates a defect. Further test currents 8 can be measured between further connection elements 7. The test currents 8 can each be compared with a threshold value or with each other. Defects are localized by assigning the measured values to the position of the contact layer 3.

Provision can be made to define a tolerance range around a determined average value. It can be provided that test currents 8 which are outside the tolerance range indicate a defect. A local region of the chip 1 can be assigned to these determined test currents 8. A warning signal can indicate that the localized region of the chip 1 has a defective contact.

A resistance can first be calculated from a measured test current 8. The calculated resistance can be compared with a threshold value. A deviation from the threshold value can indicate a defect in the corresponding contact. A warning signal can be output to a higher-level system or to a user. By way of example, the limit is 100 Ω.

The conductive adhesive 4 can in particular have a threshold value in the low-ohm range. In the event of a failure, the threshold value of the electrical contact can be in the mega- or gigaohm range. Resistances of the electrical contacts on the rear side of the chip 1 are usually in the lower ohm range. Depending on the chip area on the rear side, these are typically often less than 1 ohm.

If such a connection to the rear side of the chip fails, the resistance can increase by a factor of 1000 to 1,000,000 or more. Such an increase can be easily detected electronically. When graphite or aluminum-filled adhesives are used, they are typically less conductive. They are then mostly in the kilo-ohm to mega-ohm range. Threshold values can also depend on environmental influences, for example moisture.

The threshold value can therefore be product-specific. In particular, the threshold value can be at least 0.1 Ω, at least 0.5 Ω, or at least 1 Ω. The threshold value can be less than 100 MΩ, less than 100 kΩ, or less than 100 Ω.

Errors can be predicted by repeating and comparing measurements. For this purpose, for example, a first measured test current can be compared with a second test current measured at a later point in time. The first and the second test currents were measured between the same insulated regions or between the same insulated region and the electrical contact element of the chip carrier.

The test method can in particular be suitable for testing the contacting during and/or after the manufacture of the chip module. In this case, contact resistances of at least two or more of the contact regions 3A to 3D insulated from each other can be compared with each other or with a good/bad value by a current-voltage measurement. This measurement can be integrated into the manufacturing process as a sample measurement. It can also be provided that during the manufacturing process of the chip module, all contacts or substantially all contacts are checked according to the test method.

The test procedure can be carried out as part of the quality control of the chip module. After completion of the module, in what is usually called the final test, the contact resistances of at least two or more of the insulated contact surfaces can be compared with each other or with at least one threshold value, for example in the form of a good/bad value, by a current-voltage measurement with a suitable contacting and measuring device, for example the test arrangement described. This measurement can be integrated into the quality control process as a sample measurement. It can also be provided that, during the quality control of the chip module, all contacts or substantially all contacts are checked in accordance with the test method.

The test procedure can be carried out as part of reliability tests for the purpose of developing, changing, qualifying, and quality assurance of the chip module. With suitable contacting and measuring devices, in particular the test arrangement described above, contact resistances of at least two or more of the insulated contact surfaces can be detected by a current-voltage measurement. This can take place as a function of various parameters such as time, temperature, humidity, etc. The measured value detection can take place continuously.

In an embodiment, the test method described can be applied while the chip module is being used, for example in a LIDAR sensor. The measured value detection can take place continuously. A warning can be sent to the higher-level system if the specified threshold values are exceeded above or below. This can be particularly advantageous for safety-relevant systems, for example in vehicle safety systems. For example, failures of individual contacts of the chip module can be detected and localized, preferably in real time, and the warning signal can be used to signal a failure or loss of quality of certain contacts to a user or a system. In addition to a suddenly occurring malfunction of the chip module, the test method can therefore also detect an incipient malfunction of the chip module.

The present invention improves the stability and reliability of the connection between the chip 1 and the chip carrier, and/or creates a possibility of checking the state of this electrical and mechanical connection and, in particular, of monitoring it permanently.

The essential function of secure rear-side contacting of a chip 1 can be tested not only in the manufacturing process itself, but this test can be carried out permanently in an application—i.e., while the chip module is being used, for example in a motor vehicle or a drone, and again, for example in a LIDAR sensor. In the case of safety-critical applications in particular, this can offer the possibility of detecting a failure at an early stage and reacting accordingly.

What is claimed is:

1. A chip module, comprising:
a chip having a front side and a rear side;
a chip carrier having an upper side facing the chip;
a contact layer formed of an electrically conductive material and arranged on the upper side of the chip carrier between the rear side of the chip and the upper side of the chip carrier; and
an electrically conductive adhesive arranged on an upper side of the contact layer facing the chip, the electrically conductive adhesive connecting the upper side of the contact layer and the rear side of the chip, the contact layer has a plurality of regions electrically insulated from each other and each electrically connected to the chip by the electrically conductive adhesive.

2. The chip module of claim 1, wherein the plurality of regions are at least three regions.

3. The chip module of claim 1, wherein the electrically conductive adhesive does not electrically connect the regions of the contact layer.

4. The chip module of claim 1, wherein the chip has a length and/or a width that is less than a length and/or a width of the contact layer, and the contact layer protrudes beyond the chip.

5. The chip module of claim 1, wherein the chip has a length and/or a width that is greater than a length and/or a width of the contact layer, and the chip covers the contact layer.

6. The chip module of claim 1, wherein the chip and contact layer are centered with a surface center point of the upper side of the contact layer at a minimal distance from a surface center point of the rear side of the chip, a surface of the contact layer is defined by a plurality of outer edges of the plurality of regions.

7. The chip module of claim 1, wherein at least two of the plurality of regions have a plated-through hole extending from the upper side of the chip carrier to an underside of the chip carrier.

8. The chip module of claim 7, wherein the plated-through hole has a soldering surface and/or a solder ball on the underside of the chip carrier.

9. The chip module of claim 7, wherein the plated-through hole has a passage extending through the plated-through hole.

10. The chip module of claim 9, wherein the electrically conductive adhesive is arranged in the passage and/or between the plated-through hole and the rear side of the chip.

11. The chip module of claim 1, further comprising an electrically non-conductive adhesive arranged between the chip carrier and the chip and connecting the upper side of the chip carrier to the rear side of the chip.

12. The chip module of claim 1, further comprising a housing arranged on the upper side of the chip carrier, the housing enclosing the chip and the contact layer.

13. The chip module of claim 12, wherein the housing has an optical window on the front side of the chip.

14. The chip module of claim 1, further comprising a passivation applied over at least a portion of the chip module.

15. The chip module of claim 1, further comprising an electrical contact element and a bonding wire electrically connecting the front side of the chip to the electrical contact element.

16. The chip module of claim 1, wherein the chip has a length greater than or equal to 1 mm and less than or equal to 200 mm, and/or the chip has a width greater than or equal to 1.5 mm and less than or equal to 200 mm.

17. The chip module of claim 1, wherein the chip is one of a plurality of chips.

18. A sensor, comprising:
a chip module including a chip having a front side and a rear side, a chip carrier having an upper side facing the chip, a contact layer formed of an electrically conductive material and arranged on the upper side of the chip carrier between the rear side of the chip and the upper side of the chip carrier, and an electrically conductive adhesive arranged on an upper side of the contact layer facing the chip, the electrically conductive adhesive connecting the upper side of the contact layer and the rear side of the chip, the contact layer has a plurality of regions electrically insulated from each other and each electrically connected to the chip by the electrically conductive adhesive.

19. A test arrangement, comprising:
a chip module including a chip having a front side and a rear side, a chip carrier having an upper side facing the chip, a contact layer formed of an electrically conductive material and arranged on the upper side of the chip carrier between the rear side of the chip and the upper side of the chip carrier, and an electrically conductive adhesive arranged on an upper side of the contact layer facing the chip, the electrically conductive adhesive connecting the upper side of the contact layer and the rear side of the chip, the contact layer has a plurality of regions electrically insulated from each other and each electrically connected to the chip by the electrically conductive adhesive;
a first electrical connection element in electrical contact with a first region of the plurality of regions;
a second electrical connection element in electrical contact with a second region of the plurality of regions or in electrical contact with an electrical contact element of the chip carrier; and
a current measuring device electrically connected to the first electrical connection element and the second electrical connection element, the current measuring device measuring a test current between the first electrical connection element and the second electrical connection element.

20. A method for monitoring, comprising:
providing a test arrangement including:
a chip module including a chip having a front side and a rear side, a chip carrier having an upper side facing the chip, a contact layer formed of an electrically conductive material and arranged on the upper side of the chip carrier between the rear side of the chip and the upper side of the chip carrier, and an electrically conductive adhesive arranged on an upper side of the contact layer facing the chip, the electrically conductive adhesive connecting the upper side of the contact layer and the rear side of the chip, the contact layer has a plurality of regions electrically insulated from each other and each electrically connected to the chip by the electrically conductive adhesive;
a first electrical connection element in electrical contact with a first region of the plurality of regions; and
a second electrical connection element in electrical contact with a second region of the plurality of regions or in electrical contact with an electrical contact element of the chip carrier;
measuring a test current between the first electrical connection element and the second electrical connection element;
comparing the test current with a further measured test current and/or with a threshold current value, and/or calculating a resistance from the test current and comparing the resistance to a further measured resistance and/or to a threshold resistance value; and
localizing a defect of the chip module by assigning the test current and/or the resistance to a position of the contact layer.

21. The method of claim 20, wherein the threshold resistance value is less than 100 MΩ.

22. The method of claim 20, wherein the defect is predicted by repeated and comparative measurements.

23. The method of claim 20, wherein the measuring, comparing, and localizing steps are repeated while the chip module is being used in an application.
